(19) United States
(12) Patent Application Publication
(10) Pub. No.: US 2024/0183911 A1
(43) Pub. Date: Jun. 6, 2024

(54) ANOMALY DETECTION APPARATUS AND ANOMALY DETECTION METHOD

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Hiroki TANAKA, Yokkaichi-shi, Mie (JP); Keisuke WAKAZONO, Yokkaichi-shi, Mie (JP); Yuuki SUGISAWA, Yokkaichi-shi, Mie (JP)

(21) Appl. No.: 18/552,170

(22) PCT Filed: Mar. 10, 2022
(86) PCT No.: PCT/JP2022/010466

§ 371 Date: Sep. 23, 2023

(30) Foreign Application Priority Data
Mar. 25, 2021 (JP) 2021-051023

(51) Int. Cl. G01R 31/3835; H02H 1/00; H02H 7/18

(52) U.S. Cl. CPC G01R 31/3835; H02H 1/0007; H02H 7/18

(57) ABSTRACT

An anomaly detection device for a power supply system includes: a first power supply unit; a second power supply unit; a first conductive path and a second conductive path for transmitting electric power between the first power supply unit and the second power supply unit; and a relay for controlling current through the first conductive path and the second conductive path. The anomaly detection device includes: a first voltage detector for detecting a first voltage on the first power supply unit side of the first and the second conductive paths relative to the relay; a second voltage detector for detecting a second voltage on the second power supply unit side of the first and second conductive paths relative to the relay; and a detector for detecting an anomaly based on the first voltage and the second voltage when the relay is in a cut-off state.

### CROSS-REFERENCE TO RELATED APPLICATIONS

This application is the U.S. national stage of PCT/JP2022/010466 filed on Mar. 10, 2022, which claims priority of Japanese Patent Application No. JP 2021-051023 filed on Mar. 25, 2021, the contents of which are incorporated herein.

### TECHNICAL FIELD

The present disclosure relates to an anomaly detection apparatus and an

anomaly detection method.

### BACKGROUND

JP 2018-129951A discloses an in-vehicle power supply device that supplies electric power from a power storage unit that produces a higher voltage to a power storage unit that produces a lower voltage. This in-vehicle power supply device can protect the power storage units by turning off a switch unit if the power storage unit that produces a lower voltage is reversed or unconnected, i.e. in an open state.

The device of JP 2018-129951A can detect anomalies in one power storage unit, but is not designed to detect anomalies in the other power storage unit. In practice, however, it is possible that both power storage units can enter the open state. In addition, when an attempt is made to detect anomalies in both power storage units, it is necessary to avoid a situation in which the output voltage of one power storage unit negatively affects the voltage detection at the other power storage unit.

The present disclosure has been completed based on the above circumstances, and aims to provide an anomaly detection device and an anomaly detection method that enable favorable detection of voltage anomalies on a power path to which two power supply units are connected.

### SUMMARY

An anomaly detection device, which is part of the present disclosure, is an anomaly detection device for detecting an anomaly in a power supply system. The power supply system includes a first power supply unit; a second power supply unit; a power path serving as a path for transmitting electric power between the first power supply unit and the second power supply unit; and a relay switched between a conductive state, where a current can flow through the power path, and a cut-off state, where a current flow through the power path is cut off. The anomaly detection device comprises a first voltage detector configured to detect a first voltage on the first power supply unit side of the power path relative to the relay; a second voltage detector configured to detect a second voltage on the second power supply unit side of the power path relative to the relay; and a detector configured to detect an anomaly based on the first voltage and the second voltage when the relay is in the cut-off state.

An anomaly detection method, which is part of the present disclosure, is an anomaly detection method for detecting an anomaly in a power supply system. The power supply system includes a first power supply unit; a second power supply unit; a power path serving as a path for transmitting electric power between the first power supply unit and the second power supply unit; and a relay switched between a conductive state, where a current can flow through the power path, and a cut-off state, where a current flow through the power path is cut off. The anomaly detection method comprises a first operation of switching the relay to the cut-off with use of a controller; a second operation of detecting a first voltage on the first power supply unit side of the power path relative to the relay, with use of a first voltage detector, at least after the first operation; a third operation of detecting a second voltage on the second power supply unit side of the power path relative to the relay, with use of a second voltage detector, at least after the first operation; and a fourth operation of detecting an anomaly based on the first voltage and the second voltage in the cut-off state, with use of a detector, after the second operation and the third operation have been executed.

### Advantageous Effects

According to the present disclosure, it is possible to favorably detect voltage anomalies on a power path to which two power supply units are connected.

### BRIEF DESCRIPTION OF DRAWINGS

FIG. 1 is a schematic diagram showing a configuration of a power supply system equipped with an anomaly detection device of Embodiment 1.

FIG. 2 is a schematic diagram showing a configuration of the anomaly detection device of Embodiment 1.

FIG. 3 is a flowchart showing a procedure of an anomaly detection method performed in the anomaly detection device of Embodiment 1.

FIG. 4 is a timing chart showing the operation state of a first relay unit and a second relay unit and the temporal change of a first voltage and a second voltage.

FIG. 5 is a schematic diagram showing a part of a configuration of an anomaly detection device of another embodiment.

FIG. 6 is a timing chart showing the operation state of a first relay unit and a second relay unit and the temporal change of a first voltage and a second voltage in another embodiment.

### DETAILED DESCRIPTION OF PREFERRED EMBODIMENTS

Embodiments of the present disclosure will be listed and illustrated below. Note that the features in the following items 1 to 7 may be combined in any manner as long as no contradiction arises.

An anomaly detection device, which is part of the present disclosure, is for detecting an anomaly in a power supply system. The power supply system includes: a first power supply unit; a second power supply unit; a power path serving as a path for transmitting electric power between the first power supply unit and the second power supply unit; and a relay switched between a conductive state, where a current can flow through the power path, and a cut-off state, where a current flow through the power path is cut off. The anomaly detection device comprises: a first voltage detector; a second voltage detector; and a detector. The first voltage detector is configured to detect a first voltage on the first power supply unit side of the power path relative to the relay. The second voltage detector is configured to detect a second voltage on the second power supply unit side of the power path relative to the relay. The detector is configured to detect an anomaly based on the first voltage and the second voltage when the relay is in the cut-off state.

The anomaly detection device of the item 1 can separate the power path into the first power supply unit side and the second power supply unit side by setting the relay to the cut-off state, thus making it possible to prevent the voltage at the first power supply unit and the second power supply unit from being propagated to the other side of the power path across the relay. This enables favorable detection of the voltage on both sides of the power path relative to the relay.

The anomaly detection device of the item 1 may further comprise: a controller configured to control the relay, and the controller may be configured to periodically switch the relay between the conductive state and the cut-off state.

The anomaly detection device described in the item 2 can easily detect anomalies finely without a time delay from when an anomaly occurs on the power path.

The anomaly detection device of the item 1 or 2 may further comprise: a controller configured to control the relay, and the controller may be configured to maintain the cut-off state if the detector detects an anomaly.

The anomaly detection device described in the item 3 can prevent an anomaly that has occurred on one side of the power path from being propagated to the other side of the power path.

The anomaly detection device of the item 1 or 2 may further comprise: a controller configured to control the relay, and if the detector detects an anomaly, and the controller may be configured to at least either give a notification to an external device or perform a storage operation, while maintaining the conductive state.

If an anomaly has occurred on the power path on one side but electric power still needs to be supplied to the conductive path on this side, the anomaly detection device described in the item 4 can continue to supply electric power to the conductive path on the one side by maintaining the relay in the conductive state. The configuration in which a notification is given to the external device makes it possible to give a notification that one side of the conductive path is being supplied with electric power while an anomaly has occurred on the conductive path on this side. Further, the controller stores information indicating that electric power is being supplied to the conductive path on one side although an anomaly has occurred on the conductive path on this side, thus allowing the history of the abnormal state on the conductive path to be easily referenced during maintenance.

Item 5: The anomaly detection device of any of the items 2 to 4 may further comprise a failure detection device. The failure detection device is capable of detecting a failure state, where the relay is maintained in the conductive state while the controller is performing control to set the relay to the cut-off state, and a normal state, where the relay is maintained in the cut-off state while the controller is performing control to set the relay to the cut-off state. The detector may be configured to detect an anomaly based on the first voltage and the second voltage while the controller is performing control to set the relay to the cut-off state, under a condition that the failure detection device detects the normal state.

The anomaly detection device according to the item 5 can separate failures of the relay from anomalies on the power path, thus allowing the detector to detect anomalies on the power path more reliably.

Item 6: An anomaly detection method, which is part of the present disclosure, is for detecting an anomaly in a power supply system. The power supply system includes: a first power supply unit; a second power supply unit; a power path serving as a path for transmitting electric power between the first power supply unit and the second power supply unit; and a relay switched between a conductive state, where a current can flow through the power path, and a cut-off state, where a current flow through the power path is cut off. The anomaly detection method comprises: a first operation; a second operation, a third operation, and a fourth operation. In the first operation, the relay is switched to the cut-off state with use of a controller. In the second operation, a first voltage on the first power supply unit side of the power path relative to the relay is detected with use of a first voltage detector, at least after the first operation. In the third operation, a second voltage on the second power supply unit side of the power path relative to the relay is detected with use of a second voltage detector, at least after the first operation. In the fourth operation, an anomaly is detected based on the first voltage and the second voltage in the cut-off state, with use of a detector, after the second operation and the third operation have been executed.

The anomaly detection method of the item 6 can separate the power path into the first power supply unit side and the second power supply unit side by setting the relay to the cut-off state, thus making it possible to prevent the voltage at the first power supply unit and the second power supply unit from being propagated to the other side of the power path across the relay. This enables favorable detection of the voltage on both sides of the power path relative to the relay.

Item 7: An anomaly detection program is to be used in a power supply system that includes: a first power supply unit; a second power supply unit; a power path for transmitting electric power between the first power supply unit and the second power supply unit; and a relay switched between a conductive state where a current can flow through the power path and a cut-off state where a current flow through the power path is cut off, and the anomaly detection program includes: a first step of causing a controller to switch the relay to the cut-off state; and a second step of causing a detector to perform an operation to detect an anomaly based on a first voltage on the first power supply unit side of the power path relative to the relay during a period of the cut-off state, and a second voltage on the second power supply unit side of the power path relative to the relay during the period of the cut-off state.

The anomaly detection program of the item 7 can separate the power path into the first power supply unit side and the second power supply unit side by setting the relay to the cut-off state, thus making it possible to prevent the voltage at the first power supply unit and the second power supply unit from being propagated to the other side of the power path across the relay. This enables favorable detection of the voltage on both sides of the power path relative to the relay.

### Configuration of Power Supply System

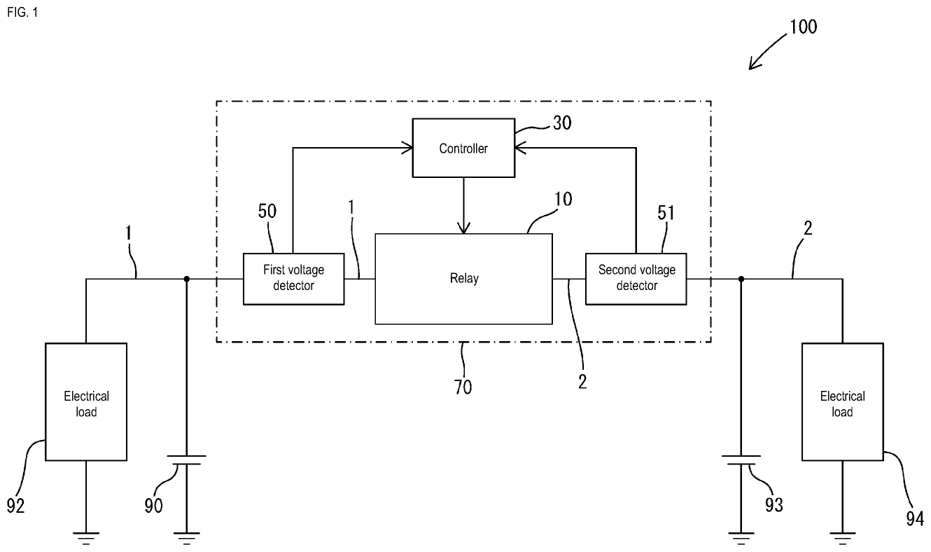

FIG. 1 illustrates a power supply system 100 equipped with an anomaly detection device 70 according to Embodiment 1. The power supply system 100 is used as a power supply to operate loads such as loads 92 and 94 in a vehicle in which the power supply system 100 is installed. The power supply system 100 includes a first power supply unit 90, a second power supply unit 93, a first conductive path 1 serving as a power path, a second conductive path 2 serving as a power path, a relay 10, and an anomaly detection device 70.

The first power supply unit 90 and the second power supply unit 93 are configured as direct-current power supplies such as lithium-ion batteries or lead-acid batteries. The output voltages of the first power supply unit 90 and the second power supply unit 93 are 12 V, for example. One end of the first conductive path 1 is electrically connected to a high-potential terminal of the first power supply unit 90. The load 92 is also electrically connected to end of the first conductive path 1 in parallel with the first power supply unit 90. The other end of the first conductive path 1 is electrically connected to one end of the relay 10. One end of the second conductive path 2 is electrically connected to a high-potential terminal of the second power supply unit 93. The load 94 is also electrically connected to end of the second conductive path 2 in parallel with the second power supply unit 93. The other end of the second conductive path 2 is electrically connected to the other end of the relay 10. The first conductive path 1 and the second conductive path 2 are paths for transmitting electric power between the first power supply unit 90 and the second power supply unit 93.

In the present disclosure, “being electrically connected” desirably refers to

a configuration in which both connected elements are connected to each other in a conductive state (a state where a current can be conducted) such that the potentials at these connected elements are equal. However, this configuration need not be the case. For example, “being electrically connected” may alternatively refer to a configuration in which two connected elements are connected in a conductive state with an electrical component interposed between the two connected elements.

The load 92 includes an electrical component that operates while receiving electric power supplied from the first power supply unit 90. The load 94 has the same configuration and function as the load 92. The power supply system 100 is configured as a system in which the load 94 is operated in place of the load 92 if an anomaly occurs in the load 92, thereby enabling the load 94 to maintain the function of the load 92 even in the event of the anomaly in the load 92.

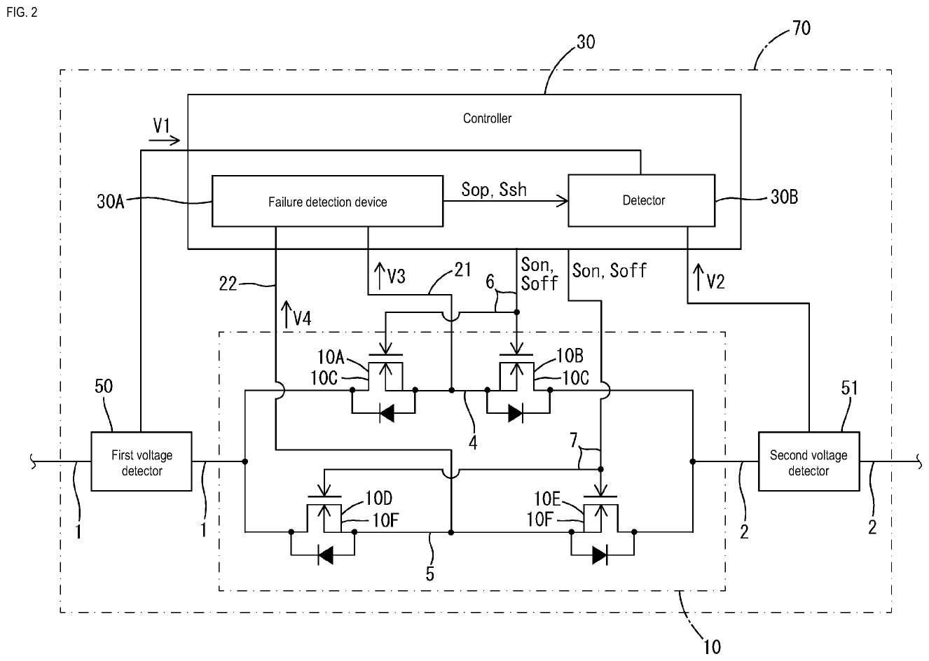

The relay 10 is disposed between the first power supply unit 90 and the second power supply unit 93. The relay 10 switches between a conductive state, in which a current can flow through the first conductive path 1 and the second conductive path 2, and a cut-off state, in which a current flow through the first conductive path 1 and the second conductive path 2 is cut off. The relay 10 includes a first relay unit 10C and a second relay unit 10F that are electrically connected in parallel, as shown in FIG. 2. The first relay unit 10C is constituted by two switch elements 10A and 10B that are connected in series in different orientations. The second relay unit 10F is constituted by two switch elements 10D and 10E that are connected in series in different orientations.

Embodiment 1 illustrates, as a typical example, the case where each of the first relay unit 10C and the second relay unit 10F is constituted by two N-channel MOSFETs (Metal-Oxide-Semiconductor Field Effect Transistors). In the case where each of the switch elements 10A and 10B of the first relay unit 10C is constituted by an N-channel MOSFET, the sources of these switch elements 10A and 10B are electrically connected to each other via a first intermediate conductive path 4. The drain of the switch element 10A is connected to an end portion of the first conductive path 1, and the drain of the switch element 10B is connected to the second conductive path 2. The first intermediate conductive path 4 is electrically connected to a failure detection device 30A via a first signal line 21.

In the case where each of the switch elements 10D and 10E of the second relay unit 10F is constituted by an N-channel MOSFET, the sources of these switch elements 10D and 10E are electrically connected to each other via a second intermediate conductive path 5. The drain of the switch element 10D is connected to an end portion of the first conductive path 1, and the drain of the switch element 10E is connected to the second conductive path 2. The second intermediate conductive path 5 is electrically connected to the failure detection device 30A via a second signal line 22. This allows the first relay unit 10C and the second relay unit 10F to have a configuration in which the two MOSFETs are arranged in series in a so-called face-to-face state (i.e. an arrangement in which body diodes are in opposite orientations).

The gates of the switch elements 10A, 10B, 10D, and 10E are electrically connected to a controller 30. Specifically, the gates of the switch elements 10A and 10B are electrically connected to the controller 30 via a first wire 6. The gates of the switch elements 10D and 10E are electrically connected to a controller 30 via a second wire 7. This configuration enables the controller 30 to separately control the first relay unit 10C and the second relay unit 10F.

### Configuration of Anomaly Detection Device

The anomaly detection device 70 includes a first voltage detector 50, a second voltage detector 51, the controller 30, the failure detection device 30A, and a detector 30B.

The first voltage detector 50 is provided on the first conductive path 1, which is a power path located on the first power supply unit 90 side relative to the relay 10. The first voltage detector 50 detects a first voltage V1 at a predetermined position on the first conductive path 1 (a position on the first power supply unit 90 side relative to the relay 10) and gives a detection value corresponding to the first voltage V1 to the detector 30B. The detector 30B is capable of identifying a voltage value at the predetermined position on the first conductive path 1 based on the detection value input from the first voltage detector 50.

The second voltage detector 51 is provided on the second conductive path 2, which is a power path located on the second power supply unit 93 side relative to the relay 10. The second voltage detector 51 detects a second voltage V2 at a predetermined position on the second conductive path 2 (a position on the second power supply unit 93 side relative to the relay 10) and gives a detection value corresponding to the second voltage V2 to the detector 30B. The detector 30B is capable of identifying a voltage value at the predetermined position on the second conductive path 2 based on the detection value input from the second voltage detector 51.

The controller 30 is mainly constituted by a microcomputer, for example, and has a processor such as a CPU (Central Processing Unit), memories such as a ROM (Read Only Memory) and a RAM (Random Access Memory), an A/D converter, and the like. The controller 30 performs on-control by giving an on-signal Son to the gates of the switch elements 10A, 10B, 10D, and 10E via the first wire 6 and the second wire 7. Thus, the relay 10 (switch elements 10A, 10B, 10D, and 10E) turns on and enters the conductive state in which a current can flow between the first conductive path 1 and the second conductive path 2. The controller 30 performs off-control by giving an off-signal Soff to the gates of the switch elements 10A, 10B, 10D, and 10E via the first wire 6 and the second wire 7. Thus, the relay 10 (switch elements 10A, 10B, 10D, and 10E) turns off and enters the cut-off state. In the cut-off state, the relay 10 does not allow a current to flow in either direction (i.e. either toward the first conductive path 1 or the second conductive path 2), and the current flow between the first conductive path 1 and the second conductive path 2 is completely cut off in this state. That is, the controller 30 is capable of controlling the relay 10.

The controller 30 is also capable of periodically switching the switch elements 10A, 10B, 10D, and 10E of the relay 10 between the conductive state and the cut-off state if no short-circuit failure or open failure has occurred in the relay 10.

The failure detection device 30A is included in the controller 30, for example. The failure detection device 30A is capable of detecting failures of the switch elements 10A, 10B, 10D, and 10E of the relay 10. The failure detection device 30A performs a failure detection operation if a start switch (not shown; e.g. ignition switch) turns on. The failure detection device 30A obtains, via the first signal line 21, a third voltage V3, which is a voltage on the first intermediate conductive path 4, and obtains, via the second signal line 22, a fourth voltage V4, which is a voltage on the second intermediate conductive path 5.

The failure detection device 30A detects failures of the switch elements 10A and 10B based on the on/off-control state of the switch elements 10A and 10B and the third voltage V3, while causing the controller 30 to turn on the switch elements 10D and 10E. For example, the failure detection device 30A performs open failure detection processing to detect an open failure of the switch elements 10A and 10B based on the third voltage V3. An open failure refers to a failure in which a switch element does not switch from off to on. If the third voltage V3 is not equal to the voltage on the first conductive path 1 or the second conductive path 2 although an on-signal Son is output from the controller 30 to the switch elements 10A and 10B, the failure detection device 30A determines that an open failure has occurred in both the switch elements 10A and 10B. This state is a failure state where the relay 10 is maintained in the cut-off state while the controller 30 is performing control to set the relay 10 to the conductive state. The failure detection device 30A thus detects an open failure of the switch elements 10A and 10B. For example, if the failure detection device 30A detects an open failure of the switch elements 10A and 10B, the failure detection device 30A outputs an open failure signal Sop to the detector 30B.

While the on-signal Son is output from the controller 30 to the switch elements 10A and 10B, the failure detection device 30A does not detect an open failure of the switch elements 10A and 10B if the third voltage V3 is equal to the voltage on the first conductive path 1 or the second conductive path 2. This state is a normal state where the relay 10 is maintained in the conductive state while the controller 30 is performing control to set the relay 10 to the conductive state. In this case, the failure detection device 30A does not output the open failure signal Sop to the detector 30B.

The failure detection device 30A also performs short-circuit failure detection processing to detect a short-circuit failure of the switch elements 10A and 10B based on the third voltage V3. A short-circuit failure refers to a failure in which a switch element does not switch from on to off. If the third voltage V3 is equal to the voltage on the first conductive path 1 or the second conductive path 2 although an off-signal Soff is output from the controller 30 to the switch elements 10A and 10B, the failure detection device 30A determines that a short-circuit failure has occurred in the switch element 10A and/or 10B. This state is a failure state where the relay 10 is maintained in the conductive state although the controller 30 is performing control to set the relay 10 to the cut-off state. The failure detection device 30A thus detects a short-circuit failure in the switch elements 10A and 10B. For example, if the failure detection device 30A detects a short-circuit failure of the switch elements 10A and/or 10B, the failure detection device 30A outputs a short-circuit failure signal Ssh to the detector 30B.

While the off-signal Soff is output from the controller 30 to the switch elements 10A and 10B, the failure detection device 30A does not detect a short-circuit failure in the switch elements 10A and 10B if the third voltage V3 is not equal to the voltage on the first conductive path 1 or the second conductive path 2. This state is a normal state where the relay 10 is maintained in the cut-off state while the controller 30 is performing control to set the relay 10 to the cut-off state. In this case, the failure detection device 30A does not output the short-circuit failure signal Ssh to the detector 30B. The failure detection device 30A can thus detect the failure state and the normal state of the relay 10.

The failure detection device 30A detects failures of the switch elements 10D and 10E based on the on/off-control state of the switch elements 10D and 10E and the fourth voltage V4, while causing the controller 30 to turn on the switch elements 10A and 10B. The method of detecting failures of the switch elements 10D and 10E is the same as the above-described method of detecting failures of the switch elements 10A and 10B, and a description thereof is therefore omitted. The failure detection device 30A outputs the short-circuit failure signal Ssh to the detector 30B upon detecting a short-circuit failure of the switch elements 10D and 10E, and outputs the open failure signal Sop to the detector 30B upon detecting an open failure of the switch elements 10D and 10E.

The detector 30B is included in the controller 30, for example. The detector 30B is configured to receive the input of the first voltage V1 on the first conductive path 1 and the second voltage V2 on the second conductive path 2 from the first voltage detector 50 and the second voltage detector 51. The detector 30B detects an anomaly based on the first voltage and the second voltage while the controller 30 is performing control to set the relay 10 to the cut-off state, under the condition that the failure detection device 30A has detected the normal state. Based on the first voltage V1 and the second voltage V2, the detector 30B detects anomalies such as ground faults occurring on the first conductive path 1 and the second conductive path 2, disconnection of the first power supply unit 90 from the first conductive path 1, and disconnection of the second power supply unit 93 from the second conductive path 2.

Specifically, if the difference between the first voltage V1 input from the first voltage detector 50 and the output voltage (12 V) of the first power supply unit 90 is at least a predetermined threshold, the detector 30B determines that the power path is in the abnormal state (i.e. detects an anomaly). If the difference between the first voltage V1 input from the first voltage detector 50 and the output voltage of the first power supply unit 90 is less than the predetermined threshold, the detector 30B determines that the power path is in the normal state (i.e. does not detect an anomaly).

If the difference between the second voltage V2 input from the second voltage detector 51 and the output voltage (12 V) of the second power supply unit 93 is at least a predetermined threshold, the detector 30B determines that the power path is in the abnormal state (i.e. detects an anomaly). If the difference between the second voltage V2 input from the second voltage detector 51 and the output voltage of the second power supply unit 93 is less than the predetermined threshold, the detector 30B determines that the power path is in the normal state (i.e. does not detect an anomaly).

### Operation of Anomaly Detection Device

The following is a description of an example of the anomaly detection method by which the anomaly detection device 70 detects an anomaly.

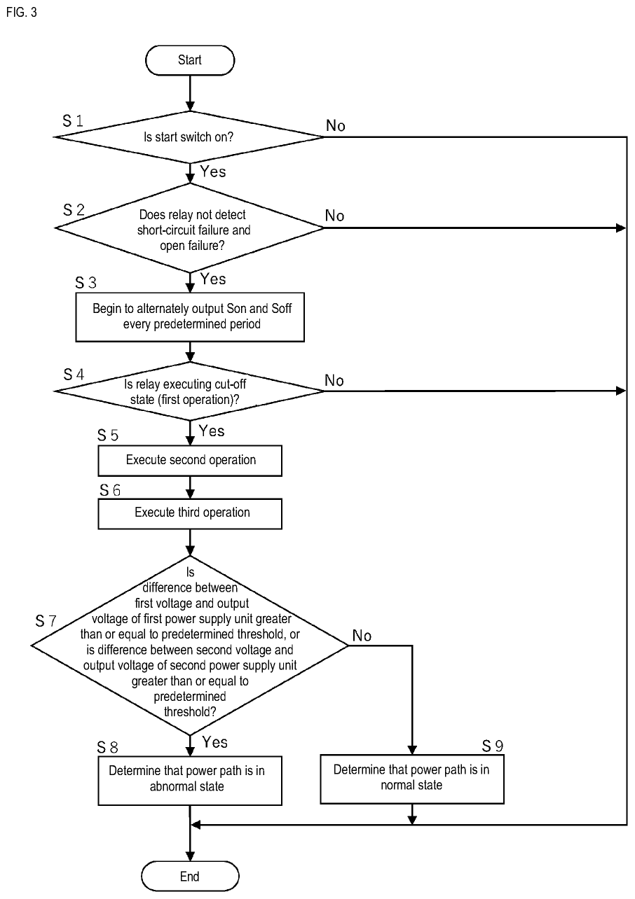

First, the start switch turns on (Yes in step S1). Then, the processing proceeds to step S2, and the failure detection device 30A performs a fault detection operation (open failure detection processing and short-circuit failure detection processing). If the start switch is not turned on in step S1 (No in step S1), the processing shown in FIG. 3 ends.

If, in step S2, the failure detection device 30A does not detect a short-circuit failure or an open failure of any of the switch elements 10A, 10B, 10D, and 10E (No in step S2), the failure detection device 30A does not output either the short-circuit failure signal Ssh or the open failure signal Sop to the detector 30B. Then, the processing proceeds to step S3, and the controller 30 begins to alternately output the on-signal Son and the off-signal Soff to the switch elements 10A, 10B, 10D, and 10E of the relay 10 every predetermined period. The controller 30 thus periodically switches the relay 10 between the conductive state and the cut-off state.

In step S3, the controller 30 periodically and alternately executes a first operation to switch the switch elements 10A, 10B, 10D, and 10E of the relay 10 to the cut-off state, and a conduction-establishing operation to switch the switch elements 10A, 10B, 10D, and 10E to the conductive state. The first operation refers to the state where the controller 30 is performing off-control to output the off signal Soff to the switch elements 10A, 10B, 10D, and 10E. Thus, each of the switch elements 10A, 10B, 10D, and 10E enters the cut-off state between the source and the drain. “Conduction-establishing operation” refers to the state where the controller 30 is performing on-control to output the on-signal Son to the switch elements 10A, 10B, 10D, and 10E. Thus, each of the switch elements 10A, 10B, 10D, and 10E enters the conductive state between the source and the drain.

If, in step S2, the failure detection device 30A detects a short-circuit failure of any of the switch elements 10A, 10B, 10D, and 10E (Yes in step S2), the failure detection device 30A outputs the short-circuit failure signal Ssh to the detector 30B. Then, the processing in FIG. 3 ends. If, in step S2, the failure detection device 30A detects an open failure, the failure detection device 30A outputs the open failure signal Sop to the detector 30B and ends the processing in FIG. 3. The detector 30B does not perform anomaly detection if the short-circuit failure signal Ssh or the open failure signal Sop is input thereto. That is, if the failure detection device 30A has detected a short-circuit failure in the relay 10 (i.e. the relay 10 turns on while off-control is being performed), the detector 30B does not perform anomaly detection. Note that the detector 30B may also be configured to perform anomaly detection if an open failure has occurred in either the first relay unit 10C or the second relay unit 10F and the other one has not failed.

In step S4, it is determined whether or not the controller 30 is executing the first operation. If, in step S4, the controller is not executing the first operation (i.e. in a state of performing on-control to output the on-signal Son to the switch elements 10A, 10B, 10D, and 10E; No in step S4), the processing in FIG. 3 ends.

If, in step S4, the controller 30 is performing off-control to output the off-signal Soff to the switch elements 10A, 10B, 10D, and 10E (Yes in step S4), the processing proceeds to step S5. In step S5, the first voltage detector 50 executes the second operation to detect the first voltage V1 on the first power supply unit 90 side of the first conductive path 1 relative to the relay 10. Specifically, in the second operation, the first voltage detector 50 detects the first voltage V1 at a predetermined position on the first conductive path 1 (a position on the first power supply unit 90 side relative to the relay 10) and gives a detection value corresponding to the first voltage V1 to the detector 30B.

Next, the processing proceeds to step S6. After the first operation, the second voltage detector 51 performs a third operation to detect the second voltage V2 on the second power supply unit 93 side of the second conductive path 2 relative to the relay 10. Specifically, in the third operation, the second voltage detector 51 detects the second voltage V2 at a predetermined position on the second conductive path 2 (on the second power supply unit 93 side relative to the relay 10) and gives a detection value corresponding to the second voltage V2 to the detector 30B.

Next, the processing proceeds to step S7 after the second operation and

the third operation have been executed, and the detector 30B executes a fourth operation to detect an anomaly based on the first voltage V1 and the second voltage V2 in the cut-off state. In step S7, the detector 30B detects an anomaly based on the first voltage and the second voltage when the controller 30 is performing control to set the relay 10 to the cut-off state in step S4, under the condition that the failure detection device 30A has detected the normal state in step S2. The processing proceeds to step S8 if the detector 30B determines in step S7 that the difference between the first voltage V1 and the output voltage (12 V) of the first power supply unit 90 is greater than or equal to the predetermined threshold, or the difference between the second voltage V2 and the output voltage (12 V) of the second power supply unit 93 is greater than or equal to the predetermined threshold (Yes in step S7). In step S8, the detector 30B determines that the power path is in the abnormal state (i.e. detects an anomaly). The controller 30 then continues to output the off-signal Soff to the switch elements 10A, 10B, 10D, and 10E. That is, the controller 30 maintains the cut-off state if the detector 30B detects an anomaly. Then, the processing in FIG. 3 ends.

The processing proceeds to step S9 if the detector 30B determines that the difference between the first voltage V1 and the output voltage of the first power supply unit 90 is smaller than the predetermined threshold, and the difference between the second voltage V2 and the output voltage of the second power supply unit 93 is smaller than the predetermined threshold (No in step S7). In step S9, the detector 30B determines that the power path is in the normal state (i.e. does not detect an anomaly). The controller 30 then outputs the on-signal Son to the switch elements 10A, 10B, 10D, and 10E. That is, the controller 30 switches the relay 10 from the cut-off state to the conductive state if the detector 30B does not detect an anomaly on the power path. Then, the processing in FIG. 3 ends.

### Example of Operation Performed by Anomaly Detection Device

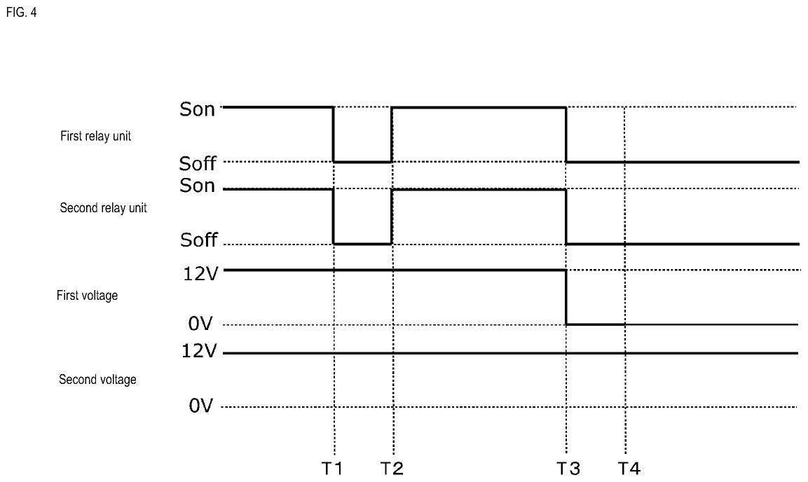

An example of operation performed by the anomaly detection device 70 will be described with reference to FIG. 4 and other figures.

If the failure detection device 30A has not detected a failure of any of the switch elements 10A, 10B, 10D, and 10E, the controller 30 begins to alternately output the on-signal Son and the off-signal Soff to the switch elements 10A, 10B, 10D, and 10E every predetermined period.

As shown in FIG. 4, at time T1, the controller 30 switches the signal output to the first relay unit 10C and the second relay unit 10F (switch elements 10A, 10B, 10D, and 10E) from the on-signal Son to the off-signal Soff. Between time T1 and time T2, the controller 30 continues to output the off-signal Soff to the switch elements 10A, 10B, 10D, and 10E. From time T1 to time T2, the relay 10 is in the cut-off state where the current flow through the first conductive path 1 and the second conductive path 2 is cut off (Yes in step S4 in FIG. 3). From time T1 to time T2, the detector 30B executes the second to fourth operations and determines whether the power path is in the abnormal state or the normal state (steps S5 to S9 in FIG. 3).

Between time T1 and time T2, the first voltage V1 on the first conductive path 1 is equal to the output voltage (12 V) at the first power supply unit 90, and the second voltage V2 on the second conductive path 2 is equal to the output voltage (12 V) at the second power supply unit 93. That is, the difference between the first voltage V1 and the output voltage at the first power supply unit 90 is smaller than the predetermined threshold, and the difference between the second voltage V2 and the output voltage at the second power supply unit 93 is smaller than the predetermined threshold (No in step S7 in FIG. 3). In this case, the detector 30B determines that the power path is in the normal state (step S9 in FIG. 3).

Next, at time T2, the controller 30 switches the signal output to the first relay unit 10C and the second relay unit 10F (switch elements 10A, 10B, 10D, and 10E) from the off-signal Soff to the on-signal Son. From time T2 to time T3, the relay 10 is in the conductive state where a current can flow through the first conductive path 1 and the second conductive path 2 (No in step S4 in FIG. 3). Accordingly, from time T2 to time T3, the detector 30B does not execute the second to fourth operations. That is, when the relay 10 is in the conductive state, the detector 30B does not determine whether the power path is in the abnormal state or the normal state.

Next, at time T3, the controller 30 switches the signal output to the first relay unit 10C and the second relay unit 10F (switch elements 10A, 10B, 10D, and 10E) from the on-signal Son to the off-signal Soff. Between time T3 and time T4, the controller 30 continues to output the off-signal Soff to the switch elements 10A, 10B, 10D, and 10E. From time T3 to time T4, the relay 10 is in the cut-off state where the current flow through the first conductive path 1 and the second conductive path 2 is cut off (Yes in step S4 in FIG. 3). From time T3 to time T4, the detector 30B executes the second to fourth operations and determines whether the power path is in the abnormal state or the normal state (steps S5 to S9 in FIG. 3).

At time T3, the first voltage V1 on the first conductive path 1 changes from the voltage equal to the output voltage of the first power supply unit 90 to 0 V. The second voltage V2 on the second conductive path 2 is unchanged at the voltage equal to the output voltage (12 V) of the second power supply unit 93. At this time, the difference between the first voltage V1 and the output voltage of the first power supply unit 90 is greater than or equal to the predetermined threshold, and the difference between the second voltage V2 and the output voltage at the second power supply unit 93 is smaller than the predetermined threshold (Yes in step S7 in FIG. 3). Then, the detector 30B determines that the power path is in the abnormal state (step S8 in FIG. 3). The anomaly detection device 70 thus detects an anomaly on the power path. After time T4, the controller 30 continues to output the off-signal Soff to the first relay unit 10C and the second relay unit 10F (switch elements 10A, 10B, 10D, and 10E). This prevents an anomaly that has occurred on the first conductive path side from being propagated to the second conductive path side.

Next, effects of the present configuration will be illustrated.

The anomaly detection device 70 of the present disclosure is used in the power supply system 100 and detects anomalies. The power supply system 100 includes a first power supply unit 90, a second power supply unit 93, a first conductive path 1, a second conductive path 2, and a relay 10. The first conductive path 1 and the second conductive path 2 are paths for transmitting electric power between the first power supply unit 90 and the second power supply unit 93. The relay 10 switches between a conductive state, in which a current can flow through the first conductive path 1 and the second conductive path 2, and a cut-off state, in which the current flow through the first conductive path 1 and the second conductive path 2 is cut off. The anomaly detection device 70 includes a first voltage detector 50, a second voltage detector 51, and a detector 30B. The first voltage detector 50 detects the first voltage V1 on the first power supply unit 90 side of the first conductive path 1 and the second conductive path 2 relative to the relay 10. The second voltage detector 51 detects the second voltage V2 on the second power supply unit 93 side of the first conductive path 1 and the second conductive path 2 relative to the relay 10. The detector 30B detects an anomaly based on the first voltage V1 and the second voltage V2 when the relay 10 is in the cut-off state.

According to this configuration, the first conductive path 1 and the second conductive path 2 can be separated from each other on the first power supply unit 90 side and the second power supply unit 93 side, respectively, by setting the relay 10 to the cut-off state. This can prevent the voltage at the first power supply unit 90 or the second power supply unit 93 from being propagated to the power path on the opposite side of the relay 10. As a result, it is possible to favorably detect the voltage on the first conductive path 1 and the second conductive path 2 on the respective sides of the relay 10.

The anomaly detection device 70 of the present disclosure includes the controller 30, which controls the relay 10, and the controller 30 periodically switches the relay 10 between the conductive state and the cut-off state. According to this configuration, an anomaly can easily be detected without a time delay from when the anomaly occurred on the first conductive path 1 or the second conductive path 2.

The anomaly detection device 70 of the present disclosure includes the controller 30, which controls the relay 10, and the controller 30 maintains the cut-off state if the detector 30B detects an anomaly. According to this configuration, an anomaly that has occurred on the power path on one side from being propagated to the power path on the other side.

The anomaly detection device 70 of the present disclosure includes a failure detection device 30A. The failure detection device 30A can detect the failure state and the normal state. “Failure state” refers to a state where the relay 10 is maintained in the conductive state while the controller 30 is performing control to set the relay 10 to the cut-off state. “Normal state” refers to a state where the relay 10 is maintained in the cut-off state while the controller 30 is performing control to set the relay 10 to the cut-off state. The detector 30B detects an anomaly based on the first voltage V1 and the second voltage V2 while the controller 30 is performing control to set the relay 10 to the cut-off state, under the condition that the failure detection device 30A detects the normal state. According to this configuration, failures of the relay 10 and anomalies on the first conductive path 1 and the second conductive path 2 can be separately detected, thus allowing the detector 30B to detect anomalies on the first conductive path 1 and the second conductive path 2 more reliably.

The anomaly detection method of the present disclosure is used in a power supply system 100 and detects anomalies. The power supply system 100 includes a first power supply unit 90, a second power supply unit 93, a first conductive path 1, a second conductive path 2, and a relay 10. The first conductive path 1 and the second conductive path 2 are paths for transmitting electric power between the first power supply unit 90 and the second power supply unit 93. The relay 10 switches between a conductive state, in which a current can flow through the first conductive path 1 and the second conductive path 2, and a cut-off state, in which the current flow through the first conductive path 1 and the second conductive path 2 is cut off. The anomaly detection method includes a first operation, a second operation, a third operation, and a fourth operation. In the first operation, the controller 30 switches the relay 10 to the cut-off state. In the second operation, which is performed after the first operation, the first voltage detector 50 detects the first voltage V1 on the first power supply unit 90 side of the first conductive path 1 and the second conductive path 2 relative to the relay 10. In the third operation, which is performed after the first operation, the second voltage detector 51 detects the second voltage V2 on the second power supply unit 93 side of the first conductive path 1 and the second conductive path 2 relative to the relay 10. In the fourth operation, which is performed after the second operation and the third operation have been executed, the detector 30B detects an anomaly based on the first voltage V1 and the second voltage V2 in the cut-off state.

According to this configuration, the first conductive path 1 and the second conductive path 2 can be separated from each other on the first power supply unit 90 side and the second power supply unit 93 side, respectively, by setting the relay 10 to the cut-off state. This can prevent the voltage at the first power supply unit 90 or the second power supply unit 93 from being propagated to the power path on the opposite side of the relay 10. As a result, it is possible to favorably detect the voltage on the first conductive path 1 and the second conductive path 2 on the respective sides of the relay 10.

### Other Embodiments

Note that the embodiment disclosed herein is illustrative in all respects and should not be considered restrictive. The scope of the present disclosure is not limited by the embodiment disclosed herein but is intended to encompass all the changes made within the meaning and scope equivalent to the claims.

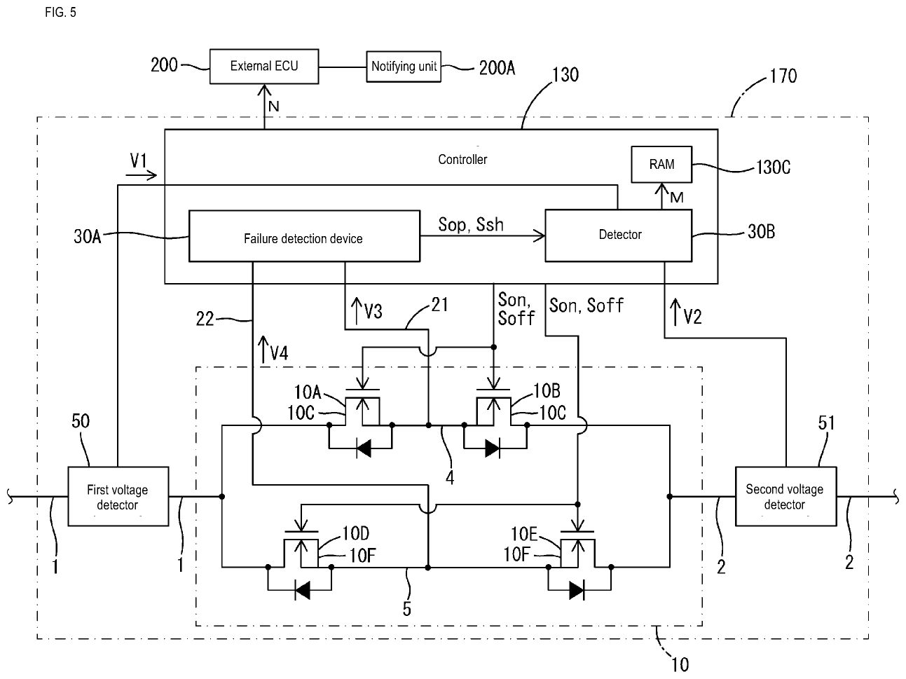

The controller 30 of Embodiment 1 maintains the cut-off state if the detector 30B detects an anomaly, but the controller may alternatively give a notification to an external device and perform a storage operation while maintaining the conductive state if the detector detects an anomaly. Specifically, if the detector 30B detects an anomaly, an anomaly detection device 170 outputs a notification signal N indicating that the detector has detected an anomaly, from the controller 130 to an external ECU 200, as shown in FIG. 5. When the external ECU 200 receives the notification signal N, a notifying unit 200A connected to the external ECU 200 produces a sound. The notifying unit 200A is, for example, a buzzer, a speaker, or the like. The user of the vehicle is thus notified that a power path is in the abnormal state. Further, at this time, the detector 30B causes the RAM 130C or the like of the controller 130 to store anomaly information M indicating that the power path is in the abnormal state. Note that the notifying unit may alternatively be an LED. In this case, when a notification signal is input to the external ECU, the notifying unit connected to the external ECU emits light.

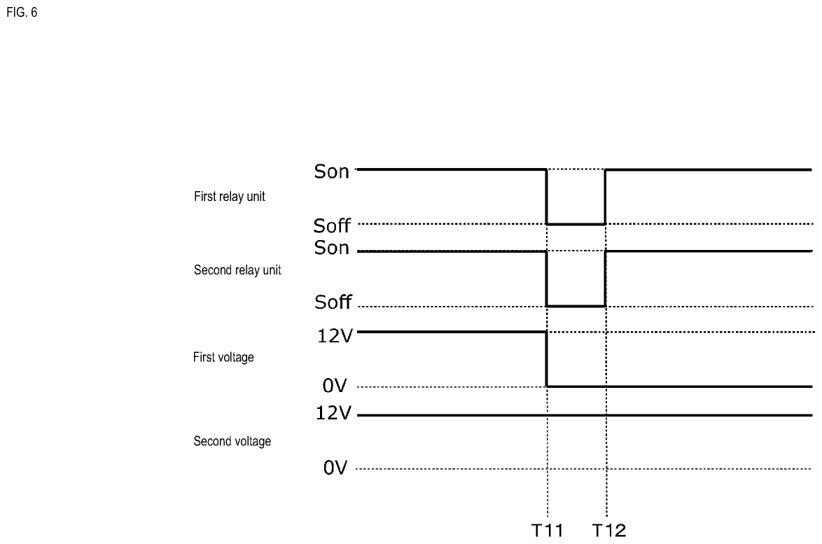

For example, at time T11, the controller 130 switches the signal output to the first relay unit 10C and the second relay unit 10F from the on-signal Son to the off-signal Soff, as shown in FIG. 6. If the first voltage V1 changes from the voltage equal to the output voltage of the first power supply unit 90 to 0 V at this timing, the detector 30B determines, from time T11 to time T12, that the power path is in the abnormal state. Thereafter, at time T12, the controller 130 switches the signal output to the first relay unit 10C and the second relay unit 10F from the off-signal Soff to the on-signal Son. Then, a current can flow through the first conductive path 1 and the second conductive path 2. In this case, for example, a resistance component is interposed between the first conductive path 1 and the second conductive path 2. Then, a current can flow from the second conductive path 2 side to the first conductive path 1 side without dropping the second voltage V2 on the second conductive path 2 to 0 V.

According to this configuration, if an anomaly has occurred on the power path on one side but electric power still needs to be supplied to the conductive path on this side, it is possible to continue to supply electric power to the conductive path on the one side by maintaining the relay in the conductive state. Further, by outputting the notification signal N to the external ECU 200, it is possible to give, using the notifying unit 200A, a notification that the conductive path on one side is being supplied with electric power although an anomaly has occurred on the conductive path on this side. Further, the controller 130 stores, in the RAM 130C or the like in the controller 130, anomaly information M indicating that electric power is being supplied to the conductive path on one side although an anomaly has occurred on the conductive path on this side, thus allowing the history of the abnormal state on the conductive path to be easily referenced during maintenance. Note that only either the output of the notification signal to the external ECU or the storage of anomaly information in the RAM may be performed.

In Embodiment 1, a configuration is described in which the first relay unit 10C and the second relay unit 10F are connected in parallel, but the number of relay units connected in parallel may also be three or more, depending on the value of the current that flows through the power path. Further, Embodiment 1 discloses that MOSFETs are used in the relay 10, but mechanical relay switches may alternatively be used in the relay.

The controller 30 of Embodiment 1 is mainly constituted by a microcomputer, but the controller 30 may alternatively be realized by a plurality of hardware circuits other than a microcomputer. Further, the failure detection device and/or the detector may be separately provided from the controller.

Embodiment 1 discloses that the output voltages of the first power supply unit 90 and the second power supply unit 93 are 12 V, but the output voltages of the first power supply unit and the second power supply unit are not limited to this voltage. Further, the output voltages of the first power supply unit and the second power supply unit need not be the same.

In Embodiment 1, the controller 30 periodically switches the switch elements 10A, 10B, 10D, and 10E between the conductive state and the cut-off state when neither a short-circuit failure nor an open failure has occurred in the relay 10. However, this need not be the case; for example, the relay may also be periodically switched between the conductive state and the cut-off state while the vehicle is traveling or parked, or if the start switch is in the off state.

In Embodiment 1, operations are executed in the order of the first operation, then the second operation and the third operation; however, operations may alternatively be executed in the order of the first operation, then the third operation and the second operation. That is, the first voltage detector may perform the second operation after at least the first operation, and the second voltage detector may perform the third operation after at least the first operation.

1. An anomaly detection device for detecting an anomaly in a power supply system, the power supply system including: a first power supply unit; a second power supply unit; a power path serving as a path for transmitting electric power between the first power supply unit and the second power supply unit; and a relay switched between a conductive state, where a current can flow through the power path, and a cut-off state, where a current flow through the power path is cut off, the anomaly detection device comprising:
a first voltage detector configured to detect a first voltage on the first power supply unit side of the power path relative to the relay;
a second voltage detector configured to detect a second voltage on the second power supply unit side of the power path relative to the relay; and
a detector configured to detect an anomaly based on the first voltage and the second voltage when the relay is in the cut-off state.

2. The anomaly detection device according to claim 1, further including;
a controller configured to control the relay,
wherein the controller is configured to periodically switch the relay between the conductive state and the cut-off state.

3. The anomaly detection device according to claim 1, further including;
a controller configured to control the relay,
wherein the controller is configured to maintain the cut-off state if the detector detects an anomaly.

4. The anomaly detection device according to claim 1, further including;
a controller configured to control the relay,
wherein if the detector detects an anomaly, the controller is configured to at least either give a notification to an external device or perform a storage operation, while maintaining the conductive state.

5. The anomaly detection device according to claim 2, further including;
a failure detection device capable of detecting a failure state, where the relay is maintained in the conductive state while the controller is performing control to set the relay to the cut-off state, and a normal state, where the relay is maintained in the cut-off state while the controller is performing control to set the relay to the cut-off state,
wherein the detector is configured to detect an anomaly based on the first voltage and the second voltage while the controller is performing control to set the relay to the cut-off state, under a condition that the failure detection device detects the normal state.

6. An anomaly detection method for detecting an anomaly in a power supply system, the power supply system including: a first power supply unit; a second power supply unit; a power path serving as a path for transmitting electric power between the first power supply unit and the second power supply unit; and a relay switched between a conductive state, where a current can flow through the power path, and a cut-off state, where a current flow through the power path is cut off, the anomaly detection method comprising:
a first operation of switching the relay to the cut-off state with use of a controller;
a second operation of detecting a first voltage on the first power supply unit side of the power path relative to the relay, with use of a first voltage detector, at least after the first operation;
a third operation of detecting a second voltage on the second power supply unit side of the power path relative to the relay, with use of a second voltage detector, at least after the first operation; and
a fourth operation of detecting an anomaly based on the first voltage and the second voltage in the cut-off state, with use of a detector, after the second operation and the third operation have been executed.

7. The anomaly detection device according to claim 2, further including;
a controller configured to control the relay,
wherein the controller is configured to maintain the cut-off state if the detector detects an anomaly.

8. The anomaly detection device according to claim 2, further including;
a controller configured to control the relay,
wherein if the detector detects an anomaly, the controller is configured to at least either give a notification to an external device or perform a storage operation, while maintaining the conductive state.

9. The anomaly detection device according to claim 3, further including;
a failure detection device capable of detecting a failure state, where the relay is maintained in the conductive state while the controller is performing control to set the relay to the cut-off state, and a normal state, where the relay is maintained in the cut-off state while the controller is performing control to set the relay to the cut-off state,
wherein the detector is configured to detect an anomaly based on the first voltage and the second voltage while the controller is performing control to set the relay to the cut-off state, under a condition that the failure detection device detects the normal state.

10. The anomaly detection device according to claim 4, further including;
a failure detection device capable of detecting a failure state, where the relay is maintained in the conductive state while the controller is performing control to set the relay to the cut-off state, and a normal state, where the relay is maintained in the cut-off state while the controller is performing control to set the relay to the cut-off state,
wherein the detector is configured to detect an anomaly based on the first voltage and the second voltage while the controller is performing control to set the relay to the cut-off state, under a condition that the failure detection device detects the normal state.
